(19) United States
(12) Patent Application Publication
(10) Pub. No.: US 2026/0328819 A1
(43) Pub. Date: Oct. 22, 2026

(54) APPARATUS FOR MEASURING THE INTENSITY OF A CURRENT FLOW ALONG AN ELONGATED ELECTRICAL CONDUCTOR BASED ON AN AUTOMATICALLY DETERMINED CORRECTION FACTOR TO COMPENSATE FOR A POSITIONAL OFFSET

(71) Applicant: WAGO Verwaltungsgesellschaft mbH, Minden (DE)

(72) Inventor: Tristan NENTWIG, Bueckeburg (DE)

(73) Assignee: WAGO Verwaltungsgesellschaft mbH, Minden (DE)

(21) Appl. No.: 19/649,751

(22) Filed: Apr. 16, 2026

(30) Foreign Application Priority Data
Apr. 17, 2025 (DE) 20 2025 102 150.1

(51) Int. Cl. G01R 19/02; G01R 15/14; G01R 19/10; G01R 19/32; G01R 35/00

(52) U.S. Cl. CPC G01R 19/02; G01R 15/148; G01R 19/10; G01R 19/32; G01R 35/005

(57) ABSTRACT

An apparatus to measure an intensity of a current flow along an electrical conductor is provided. The apparatus comprises a first, second, third, and fourth magnetic field sensor, and a circuit. A first value is derived from measured values of the first magnetic field sensor and the second magnetic field sensor. A second value is derived from measured values of the third magnetic field sensor and the fourth magnetic field sensor. A correction factor is determined from the first value and the second value based on one or more calibration values or a calibration function. The correction factor is applied to a raw value formed from measured values of the first and second magnetic field sensors or from measured values of the third magnetic field sensor and the fourth magnetic field sensor in order to determine the intensity of the current flow along the elongated electrical conductor.

This nonprovisional application claims priority under 35 U.S.C. § 119(a) to German Patent Application No. 20 2025 102 150.1, which was filed in Germany on Apr. 17, 2025, and which is herein incorporated by reference.

### BACKGROUND OF THE INVENTION

### Field of the Invention

The present disclosure relates to an apparatus for measuring the intensity of a current flow along an elongated electrical conductor (e.g., an electrical wire) using magnetic field sensors.

### Description of the Background Art

When measuring the intensity of a current flow along an elongated electrical conductor using magnetic field sensors, the accuracy of the measurement may depend on the position of the electrical conductor relative to the magnetic field sensors.

### SUMMARY OF THE INVENTION

It is therefore an object of the present invention to account for a deviation of a position of an elongated electrical conductor, from the position of an electrical conductor based on which calibration data for mapping the measured values of the magnetic field sensors to a current measurement value were generated, by automatically determining a correction factor.

The apparatus may comprise a first magnetic field sensor, a second magnetic field sensor, a third magnetic field sensor, a fourth magnetic field sensor and a circuit. The circuit may be configured to derive a first value from measured values of the first magnetic field sensor and the second magnetic field sensor. The circuit may be configured to derive a second value from measured values of the third magnetic field sensor and the fourth magnetic field sensor. The circuit may be configured to determine a correction factor from the first value and the second value based on one or more calibration values or a calibration function. The circuit may be configured to apply the correction factor to a raw value formed from measured values of the first magnetic field sensor and the second magnetic field sensor or from measured values of the third magnetic field sensor and the fourth magnetic field sensor, towards a determination of the intensity of the current flow along the elongated electrical conductor.

The apparatus may comprise a magnetically permeable structure. The magnetically permeable structure may surround the elongated electrical conductor. The cross-section of the magnetically permeable structure may have an axis of mirror symmetry, or the cross-section of the magnetically permeable structure may have an axis of mirror symmetry at least in a region around the elongated electrical conductor. A longitudinal axis of a section of the elongated electrical conductor surrounded by the permeable structure may be perpendicular to the axis of mirror symmetry. The first magnetic field sensor and the second magnetic field sensor may be arranged in a mirror-symmetric manner with respect to the axis of mirror symmetry. The third magnetic field sensor and the fourth magnetic field sensor may be arranged in a mirror-symmetric manner with respect to the axis of mirror symmetry. The third magnetic field sensor may be displaced relative to the first magnetic field sensor parallel to the axis of mirror symmetry. The fourth magnetic field sensor may be displaced relative to the second magnetic field sensor parallel to the axis of mirror symmetry.

In this regard, the term “magnetically permeable structure”, may refer to a structure made of a magnetically permeable material, e.g. a structure made of a ferromagnetic material such as a mu-metal. Furthermore, a magnetically permeable structure “surrounding the elongated electrical conductor”, may refer to a magnetically permeable structure having a concave region through which the elongated electrical conductor extends. The magnetically permeable structure may encircle the elongated electrical conductor only partially. This may allow attaching the permeable structure without (temporarily) interrupting an electrical line formed by the electrical conductor. The magnetically permeable structure may, for example, have a U-shaped cross-section.

Furthermore, a magnetically permeable structure “whose cross-section has an axis of mirror symmetry at least in a region around the electrical conductor”, may refer to a magnetically permeable structure, the cross-section of which has a section through which the electrical conductor extends and which is mirror-symmetric to an axis of mirror symmetry. The axis of mirror symmetry may (essentially) run through a center of the magnetically permeable structure. The section may be rectangular, square, oval, or circular. The electrical conductor may extend through a center of the section. The section may comprise more than 50%, more than 75%, or more than 90% of the cross-sectional area of the magnetically permeable structure. If the section comprises 100% of the cross-sectional area of the magnetically permeable structure, the cross-section of the (entire) magnetically permeable structure has an axis of mirror symmetry.

The magnetically permeable structure may be provided with a housing. The cross-section of the housing may have a V-shaped recess, and the elongated electrical conductor may extend through the V-shaped recess. The V-shaped recess may facilitate centering the electrical conductor in the magnetically permeable structure by pressing the electrical conductor towards the tapered end of the recess.

Furthermore, the term “magnetic field sensor” may refer to a sensor that provides measured values on a magnetic flux density of a magnetic field. The magnetic field sensors may be configured to measure the strength of a magnetic field perpendicular to the surface of the magnetically permeable structure facing the elongated electrical conductor. Furthermore, two mirror-symmetrically arranged magnetic field sensors may form a sensor pair. Sensor pairs may be displaced relative to each other with the displacement being, for example, in a direction parallel to the axis of mirror symmetry.

The measured values of the magnetic field sensors may be used to compensate for an offset of the elongated electrical conductor parallel to the axis of symmetry, as may result from, for example, elongated electrical conductors having different cross-sections. For instance, an elongated electrical conductor may be placed at different positions in the device as part of a calibration procedure and the measured values of the magnetic field sensors may be recorded and/or processed, so that by comparing the measured values recorded during operation with the measured values generated as part of the calibration procedure (or values derived therefrom), the position of the elongated electrical conductor may be determined or a measurement curve suitable for the actual position of the elongated electrical conductor may be automatically determined.

The circuit may be configured to determine the first value as the root mean square of a series of sums of measured values from the first magnetic field sensor and the second magnetic field sensor. The circuit may be configured to determine the second value as the root mean square of a series of sums of measured values from the third magnetic field sensor and the fourth magnetic field sensor. The magnetic field sensors may have subjected the measured values to a pre-filtering process. For example, a measured value may be a moving average determined by the sensor from a series of raw measurements. Furthermore, the circuit may be configured to subject a series of first values to filtering and a series of second values to filtering. For example, the circuit may be configured to form a first moving average from a series of first values and a second moving average from a series of second values.

The circuit may be configured to determine a quotient of the first (filtered) value and the second (filtered) value, and to determine the correction factor from the quotient, based on one or more calibration values or the calibration function.

When producing a calibration measurement series (from which the calibration values or the calibration function can be derived), an insert with one or more guides (e.g., one or more openings) may be put into the U-shaped or V-shaped recess with the one or more guides specifying an offset of an elongated electrical conductor extending through the recess parallel (and perpendicular) to the axis of mirror symmetry.

The circuit may be further configured to incorporate into the raw value a sum of measured values from the first magnetic field sensor and the second magnetic field sensor, or measured values from the third magnetic field sensor and the fourth magnetic field sensor, or to incorporate into the raw value the first (filtered) value or the second (filtered) value.

Summing the measured values from the first magnetic field sensor and the second magnetic field sensor or from the third magnetic field sensor and the fourth magnetic field sensor may help to reduce the influence of interfering fields.

The apparatus may comprise a temperature sensor. The circuit may be configured to incorporate measured values from the temperature sensor into the determination of the intensity of the current flow along the elongated electrical conductor.

For example, calibration measurement series and calibration values or calibration functions derived therefrom may be assigned to different temperatures and suitable calibration values or calibration functions may be used to determine the intensity of the current flow for a temperature measured by the temperature sensor.

Notably, the features described in connection with the apparatus may also be features of a method which relates to the use of the apparatus, and vice versa.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a depicts a schematic cross-sectional view of an apparatus according to an example;

FIG. 1b depicts a schematic top view of the apparatus shown in FIG. 1a;

FIG. 2 shows a schematic representation of a circuit comprised in the apparatus; and

FIG. 3 shows a schematic representation of a relationship between measured values of the magnetic field sensors and the correction factor.

### DETAILED DESCRIPTION

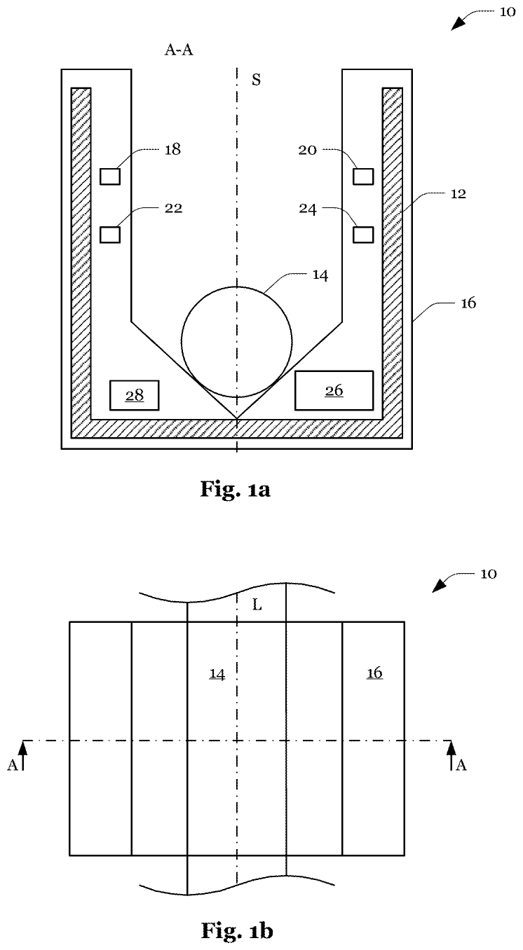

FIG. 1a shows a cross-sectional view of an apparatus 10 and FIG. 1b shows a top view of the apparatus 10 shown in FIG. 1a. The apparatus 10 comprises a magnetically permeable structure 12. The magnetically permeable structure 12 surrounds an elongated electrical conductor 14, which has a circular cross-section. Notably, the invention is not limited to elongated electrical conductors 14 with circular cross-sections. For example, the elongated electrical conductor 14 may have a triangular, square, pentagonal, hexagonal, or polygonal cross-section.

The magnetically permeable structure 12 has a U-shaped cross-section. The U-shaped cross-section has an axis S of mirror symmetry, which is perpendicular to the longitudinal axis L of the elongated electrical conductor 14. The magnetically permeable structure 12 is further provided with a housing 16. The cross-section of the housing 16 comprises a V-shaped recess through which the electrical conductor 14 extends. This centers the electrical conductor 14 relative to (i.e., in the middle between) the legs of the magnetically permeable structure 12.

The apparatus 10 further comprises a first pair of magnetic field sensors 18 and 20, which are arranged in a mirror-symmetric manner with respect to the axis S of mirror symmetry, and a second pair of magnetic field sensors 22 and 24, which are also arranged in a mirror-symmetric manner with respect to the axis S of mirror symmetry. The sensor pairs 18 and 20 and 22 and 24, in turn, are offset from each other parallel to the axis S of mirror symmetry, so that, in the cross-sectional view, the magnetic field sensors 18, 20, 22 and 24 are arranged in the corners of a rectangle.

The apparatus 10 further comprises a circuit 26 which determines the intensity of the current flow along the elongated electrical conductor 14 from the measured values of the magnetic field sensors 18, 20, 22 and 24, and a temperature sensor 28, which allows detecting temperature influences on the determination of the intensity of the current flow along the elongated electrical conductor 14 and, if necessary, taking corrective measures (with regard to the otherwise determined intensity). The measured values provided by the magnetic field sensors 18, 20, 22 and 24 and the temperature sensor 28 may be filtered, such as by calculating a moving average over a series of measured raw values, to reduce the influence of transient disturbances.

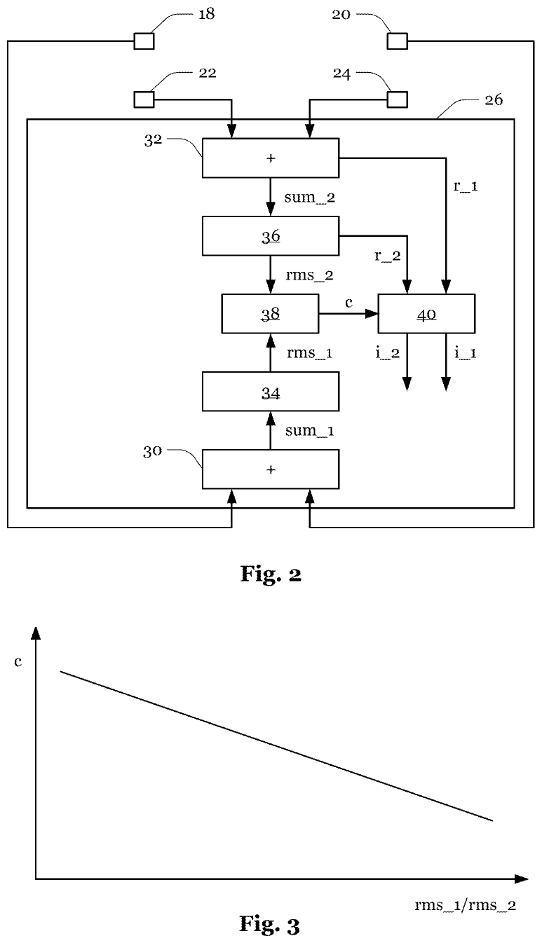

FIG. 2 illustrates the processing of the measured values from the magnetic field sensors 18, 20, 22 and 24 by the circuit 26. In functional block 30, which may be implemented by an analog circuit, a digital circuit or software, the (optionally filtered) measured values of the first magnetic field sensor 18 and the second magnetic field sensor 20 may be summed:

sum_1(t_i)=measured_value_magnetic_field_sensor_1(t_i)+measured_value_magnetic_field_sensor_2(t_i).

In functional block 32, which may be implemented by an analog circuit, a digital circuit or software, the (optionally filtered) measured values of the third magnetic field sensor 22 and the fourth magnetic field sensor 24 may be summed:

sum_2(t_i)=measured_value_magnetic_field_sensor_3(t_i)+measured_value_magnetic_field_sensor_4(t_i).

In functional block 34, which may be implemented by an analog circuit, a digital circuit or software, a root mean square rms_1 may be determined over a series of the (optionally filtered) sums of the (optionally filtered) measured values of the first magnetic field sensor 18 and the (optionally filtered) measured values of the second magnetic field sensor 20:

rms_1=sqrt((sum_1(t_i)²+sum_1(t_i+1)²+sum_1(t_i+2)²+ . . . +sum_1(t_i+n)²)/n).

n may be chosen such that the root mean square rms_1 (for alternating current) is calculated over a certain number of zero crossings or a certain window width.

In functional block 36, which may be implemented by an analog circuit, a digital circuit or software, a root mean square rms_2 may be determined over a series of the (optionally filtered) sums of the (optionally filtered) measured values of the third magnetic field sensor 22 and the (optionally filtered) measured values of the fourth magnetic field sensor 24:

rms_2=sqrt((sum_2(t_i)²+sum_2(t_i+1)²+sum_2(t_i+2)²+ . . . +sum_2(t_i+n)²)/n).

n may be chosen such that the root mean square rms_2 (for alternating current) is calculated over a certain number of zero crossings or a certain window width.

In functional block 38, which may be implemented by an analog circuit, a digital circuit or software, a correction factor c may be determined from the first value rms_1 and the second value rms_2 based on one or more calibration values or a calibration function. For example, as illustrated in FIG. 3, a correction factor may be determined within the framework of a calibration procedure for various quotients formed from rms_1 and rms_2, and based thereon calibration values or a (inter-and/or extrapolated) calibration function may be determined which assign the quotients formed from rms_1 and rms_2 to the respective correction factor c.

In functional block 40, which may be implemented by an analog circuit, a digital circuit or software, the intensity i_1 or i_2 of the current flow along the elongated electrical conductor 14 may determined from the correction factor c and a raw value r_1 and r_2, respectively

i_1=r_1/c, or

i_2=r_2/c.

The raw value r_1 or r_2 may be, for example, the (optionally filtered) sum of the (optionally filtered) measured values of the first magnetic field sensor 18 and the second magnetic field sensor 20 (or in a variation, of the third magnetic field sensor 22 and the fourth magnetic field sensor 24) to determine the instantaneous value, or the (optionally filtered) root mean square of the (optionally filtered) series of sums of the (optionally filtered) measured values of the first magnetic field sensor 18 and the second magnetic field sensor 20 (or in a variation, of the third magnetic field sensor 22 and the fourth magnetic field sensor 24) to determine the effective value.

If temperature fluctuations occur, the circuit 26 may adjust the correction factor c based on measured temperature values T or use a correction factor c(T) suitable for a measured temperature value T.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is clamed is:

1. An apparatus to measure an intensity of a current flow along an elongated electrical conductor, the apparatus comprising:
a first magnetic field sensor;
a second magnetic field sensor;
a third magnetic field sensor;
a fourth magnetic field sensor; and
a circuit that is configured:
to derive a first value from measured values of the first magnetic field sensor and the second magnetic field sensor;
to derive a second value from measured values of the third magnetic field sensor and the fourth magnetic field sensor; and
to determine a correction factor from the first value and the second value based on one or more calibration values or a calibration function; and
to apply the correction factor to a raw value formed from measured values of the first magnetic field sensor and the second magnetic field sensor or from measured values of the third magnetic field sensor and the fourth magnetic field sensor in order to determine the intensity of the current flow along the elongated electrical conductor.

2. The apparatus according to claim 1, wherein the circuit is further configured:
to determine the first value as a root mean square of a series of sums of measured values from the first magnetic field sensor and the second magnetic field sensor; and
to determine the second value as a root mean square of a series of sums of measured values from the third magnetic field sensor and the fourth magnetic field sensor.

3. The apparatus according to claim 1, wherein the circuit is further configured:
to determine a quotient of the first value and the second value and to determine the correction factor from the quotient based on the one or more calibration values or the calibration function.

4. The apparatus according to claim 1, wherein the circuit is further configured:
to incorporate a sum of measured values from the first magnetic field sensor and the second magnetic field sensor or of measured values from the third magnetic field sensor and the fourth magnetic field sensor into the raw value; or
to incorporate the first value or the second value into the raw value.

5. The apparatus according to claim 1, further comprising:
a temperature sensor,
wherein the circuit is configured to incorporate measured values from the temperature sensor into a determination of the intensity of the current flow along the elongated electrical conductor.

6. The apparatus according to claim 1, further comprising:
a magnetically permeable structure that surrounds the elongated electrical conductor and the cross-section of which has an axis of mirror symmetry or the cross-section of which has an axis of mirror symmetry at least in a region around the elongated electrical conductor,
wherein a longitudinal axis of a section of the elongated electrical conductor surrounded by the permeable structure is substantially perpendicular to the axis of mirror symmetry,
wherein the first magnetic field sensor and the second magnetic field sensor are arranged in a mirror-symmetrical manner with respect to the axis of mirror symmetry,
wherein the third magnetic field sensor and the fourth magnetic field sensor are arranged in a mirror-symmetrical manner with respect to the axis of mirror symmetry,
wherein the third magnetic field sensor is displaced relative to the first magnetic field sensor substantially parallel to the axis of mirror symmetry, and
wherein the fourth magnetic field sensor is displaced relative to the second magnetic field sensor parallel to the axis of mirror symmetry.

7. The apparatus according to claim 1, wherein an area of the cross-section around the elongated electrical conductor that has an axis of a mirror symmetry comprises more than 50%, more than 75% or more than 90% of a cross-sectional area of the magnetically permeable structure.

8. The apparatus according to claim 1, wherein the magnetically permeable structure only partially surrounds the elongated electrical conductor.

9. The apparatus according to claim 1, wherein the magnetically permeable structure has a U-shaped cross-section.

10. The apparatus according to claim 9, wherein the magnetically permeable structure is provided with a housing having a cross-section with a V-shaped recess, and wherein the elongated electrical conductor extends through the V-shaped recess.

11. The apparatus according to claim 9, wherein the magnetic field sensors are configured to measure a magnetic field strength perpendicular to a surface of the magnetically permeable structure facing the elongated electrical conductor.
